(19) United States
(12) Patent Application Publication
(10) Pub. No.: US 2021/0096312 A1
(43) Pub. Date: Apr. 1, 2021

(54) OPTICAL FIBER CIRCUIT BOARD, MULTILAYER OPTICAL FIBER CIRCUIT BOARD, AND PHOTO-ELECTRIC HYBRID CIRCUIT BOARD

(71) Applicant: SHENNAN CIRCUITS CO., LTD., SHENZHEN (CN)

(72) Inventors: GUODONG WANG, SHENZHEN (CN); HAO LUO, SHENZHEN (CN); TENGFEI YAO, SHENZHEN (CN); LING WU, SHENZHEN (CN); HAIBIN LIANG, SHENZHEN (CN)

(21) Appl. No.: 17/117,144

(22) Filed: Dec. 10, 2020

Related U.S. Application Data
(63) Continuation of application No. PCT/CN2019/094097, filed on Jun. 30, 2019.

(51) Int. Cl. G02B 6/43

(52) U.S. Cl. CPC G02B 6/43

(57) ABSTRACT

The present disclosure provides an optical fiber circuit board and a manufacturing method thereof, a multilayer optical fiber circuit board, an optical transmission device, a photo-electric hybrid circuit board, and a signal transmission device. The optical fiber circuit board includes at least two substrates stacked and spaced apart, at least one optical fiber assembly and a bonding layer. Each of the at least one optical fiber assembly is disposed between each adjacent two of the at least two substrates. Each of the at least one optical fiber assembly includes at least one optical fiber. The bonding layer is filled in a remaining space between adjacent two of the at least two substrates apart from a corresponding optical fiber assembly of the at least one optical fiber assembly to fix each of the at least one optical fiber relative to the adjacent two substrates.

### CROSS REFERENCE

The present application is a continuation-application of International (PCT) Patent Application No. PCT/CN2019/094097, filed on Jun. 30, 2019, the entire contents of which are hereby incorporated by reference in its entirety.

### TECHNICAL FIELD

The present disclosure relates to the field of circuit board technologies, and in particular, to an optical fiber circuit board and a manufacturing method thereof, a multilayer optical fiber circuit board, an optical transmission device, a photo-electric hybrid circuit board, and a signal transmission device.

### BACKGROUND

Optical interconnection refers to the use of a light guiding medium (optical fiber, optical waveguide, etc.) to realize a signal connection between a circuit board and a chip, realizing a data transmission with low power consumption, high rate, and complete signal of inter-boards/intra-boards.

The optical fiber circuit board is a method for realizing optical interconnection. The optical fiber circuit board commonly used in the related art fixes the optical fiber to a substrate through an adhesive. Such a circuit board often has an unreliable fiber position and is easily deviated from the original position. Therefore, this type of circuit board is less reliable.

### SUMMARY OF THE DISCLOSURE

The present disclosure provides an optical fiber circuit board and a manufacturing method thereof, a multilayer optical fiber circuit board, an optical transmission device, a photo-electric hybrid circuit board, and a signal transmission device.

The optical fiber circuit board includes at least two substrates stacked and spaced apart, at least one optical fiber assembly and a bonding layer. Each of the at least one optical fiber assembly is disposed between each adjacent two of the at least two substrates. Each of the at least one optical fiber assembly includes at least one optical fiber. The bonding layer is filled in a remaining space between adjacent two of the at least two substrates apart from a corresponding optical fiber assembly of the at least one optical fiber assembly to fix each of the at least one optical fiber relative to the adjacent two substrates.

The multilayer optical fiber circuit board includes the foregoing plurality of optical fiber circuit boards and at least one connecting member disposed between two adjacent optical fiber circuit boards of the plurality of optical fiber circuit boards. The plurality of optical fiber circuit boards are stacked and connected via the at least one connecting member.

The photo-electric hybrid circuit board includes at least one the foregoing circuit board of the optical fiber circuit board and the foregoing multilayer optical fiber circuit board, and a circuit wire disposed on the at least one circuit board.

### BRIEF DESCRIPTION OF THE DRAWINGS

To further illustrate technical solutions of embodiments of the present disclosure, drawings needed for description of the embodiments will be briefly introduced. Obviously, the following drawings are only some embodiments of the present disclosure. To any one of skill in the art, other drawings may be obtained without any creative work based on the following drawings.

FIG. 1 is a structural schematic view of a first optical fiber circuit board according to an embodiment of the present disclosure.

FIG. 2 is a structural schematic view of a second optical fiber circuit board according to an embodiment of the present disclosure.

FIG. 3 is a structural schematic view of a third optical fiber circuit board according to an embodiment of the present disclosure.

FIG. 4 is a partial structural schematic view of an optical fiber circuit board according to an embodiment of the present disclosure.

FIG. 5 is another partial structural schematic view of an optical fiber circuit board according to an embodiment of the present disclosure.

FIG. 6 is a structural schematic view of a multilayer optical fiber circuit board according to an embodiment of the present disclosure.

FIG. 7 is a structural schematic view of another multilayer optical fiber circuit board according to an embodiment of the present disclosure.

FIG. 8 is a structural schematic view of an optical transmission device according to an embodiment of the present disclosure.

FIG. 9 is a structural schematic view of a photo-electric hybrid circuit board according to an embodiment of the present disclosure.

FIG. 10 is a structural schematic view of a signal transmission device according to an embodiment of the present disclosure.

FIG. 11 is a front view of a circuit board and a fixing member in a signal transmission device according to an embodiment of the present disclosure.

FIG. 12 is a side view of FIG. 11.

FIG. 13 is a front view of a circuit board and a fixing member in a signal transmission device according to another embodiment of the present disclosure.

FIG. 14 is a side view of FIG. 13.

FIG. 15 is a flow chart of a method for manufacturing an optical fiber circuit board according to an embodiment of the present disclosure.

FIG. 16 is a schematic view of related structures in FIG. 15.

FIG. 17 is a flow chart of a method for manufacturing an optical fiber circuit board according to another embodiment of the present disclosure.

FIG. 18 is a schematic view of related structures in FIG. 17.

FIG. 19 is a partial flow chart of a method for manufacturing an optical fiber circuit board according to an embodiment of the present disclosure.

FIG. 20 is a related schematic view of FIG. 19.

FIG. 21 is a partial flow chart of a method for manufacturing an optical fiber circuit board according to another embodiment of the present disclosure.

FIG. 22 is a related schematic view of FIG. 21.

### DETAILED DESCRIPTION

To make any one of skill in the art to understand the technical solutions of the present disclosure, an optical fiber circuit board and a manufacturing method thereof, a multilayer optical fiber circuit board, an optical transmission device, a photo-electric hybrid circuit board, and a signal transmission device provided by the present disclosure will be described in details by referring to the drawings and the embodiments.

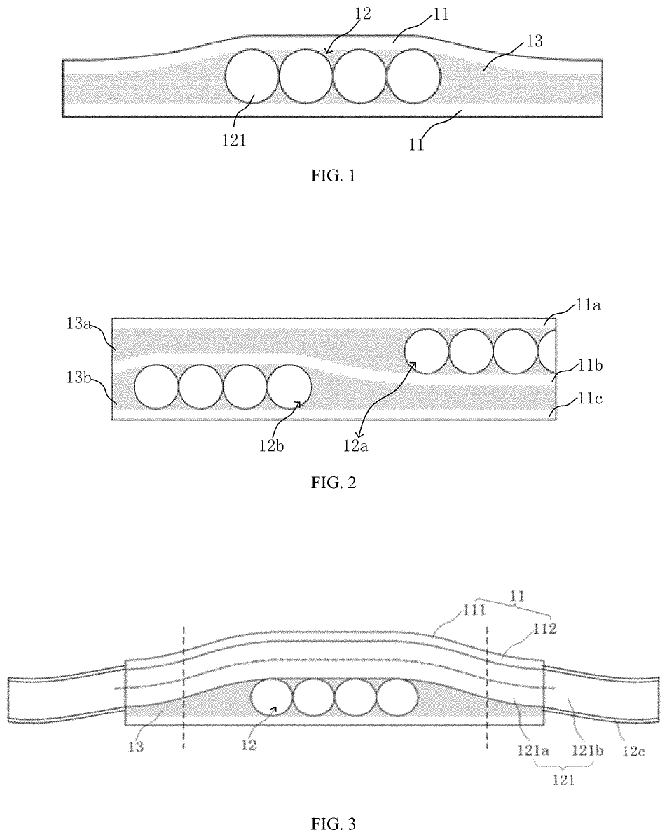

As shown in FIG. 1, FIG. 1 is a structural schematic view of a first optical fiber circuit board according to an embodiment of the present disclosure. In the embodiments, the optical fiber circuit board may be a circuit board that transmits only optical signals, or may be a circuit board that transmits a mixed signal (for example, an electrical signal) including an optical signal.

Specifically, the optical fiber circuit board may include at least two substrates 11, at least one optical fiber assembly 12, and a bonding layer 13.

The at least two substrates 11 are stacked and spaced apart. Specifically, the number of the substrates 11 may be two or three or more. The material of the substrate 11 may be a flexible composite material, such as polyimide, polyethylene terephthalate, polydimethylsiloxane, or the like.

The optical circuit board may be arranged with a thinner substrate 11 to reduce an overall weight and thickness of the optical circuit board, and increase a flexibility of the optical circuit board. However, in this case, a surface topography of the optical circuit board may be uneven. In other embodiments, a thick substrate 11 or a thin optical fiber may be applied according to actual needs to improve a flatness of the optical circuit board.

The fiber assembly 12 is disposed between each two adjacent substrates 11. Correspondingly, the number of the optical fiber assemblies 12 is one less than that of the substrates 11. That is, when the number of the substrates 11 is n, the number of the optical fibers 12 is n−1. Specifically, each optical fiber assembly 12 is disposed in a space sandwiched by two adjacent substrates 11. It should be noted that the optical fiber assembly 12 herein refers to a structure in which one or more optical fibers 121 are arranged between two adjacent substrates 11 in a certain manner. Each optical fiber assembly 12 includes at least one optical fiber 121, and specifically may be one or more optical fibers 121, one or more groups of optical fibers 121, etc. The number of the optical fibers 121 in each group of optical fibers 121 may be set according to actual needs, such as the type of a connector to be connected. For example, the number may be one, four, eight, twelve, 24, etc. The number of the groups of optical fibers 121 may also be set according to actual needs, which is not limited here.

Specifically, the optical fiber assembly 12 may include a single-layered optical fiber 121 as shown in FIG. 1 and FIG. 2, and may also include a plurality of stacked optical fibers 121 (such as two layers of optical fibers 121) as shown in FIG. 3, and may also include a plurality of optical fibers 121 stacked and arranged in a staggered manner. Of course, in practical applications, the optical fiber assembly 12 may be set according to actual needs. Further, each of the optical fibers 121 may be arranged in a straight line or in a curved shape.

Specifically, the optical fiber 121 in the optical fiber assembly 12 may be a high-temperature optical fiber. For example, a coating layer capable of withstanding a temperature higher than 100 degrees is coated on an outer surface of a core of the optical fiber. The coating layer may be made of high-temperature resistant acrylic, heat-resistant silicone, polyimide, metal, etc. Alternatively, the optical fiber 121 in the optical fiber assembly 12 may also be a common optical fiber. The peripheral coating of the core may be made of epoxy acrylate or polyacrylate, etc., which is not limited here.

The bonding layer 13 is filled in a remaining space between each two adjacent substrates 11 except the fiber assembly 12 to fix each optical fiber 121 with respect to a corresponding substrate 11. Compared with a method of the related art in which the optical fiber 121 is directly bonded to the substrate 11 by an adhesive, the optical fiber 121 may be securely fixed to the adjacent substrate 11 according to the embodiments of the present disclosure. In this way, a displacement of the optical fiber 121 due to weak fixation during prolonged use may not occur, improving a reliability of the optical fiber circuit board.

It should be noted that the optical fiber 121 is difficult to be fixed when a thickness of the bonding layer 13 is too small, and the flexibility of the optical fiber circuit board is difficult to be maintained when the thickness is too large. The thickness herein refers to a thickness of the bonding layer 13 in a direction perpendicular to a board surface of the substrate 11. In the embodiments, a thickness of a thinnest region of the bonding layer 13 between two adjacent substrates 11 is larger than one tenth of the diameter of the optical fiber 121 and less than 10 times the diameter of the optical fiber 121, or larger than half of the diameter of the optical fiber 121 and less than twice the diameter of the optical fiber 121. For example, the thickness of the thinnest region of the bonding layer 13 between two adjacent substrates 11 is one-fifth, one-half, 1 time, 2 times, 5 times, etc. of the diameter of the optical fiber 121, which is not limited herein.

Specifically, the thickness of the bonding layer 13 is not less than 50 μm, and may be 50 μm, 60 μm, 70 μm, etc. After the bonding layer 13 is arranged, a peeling strength between adjacent substrates 11 is not less than 15 N/cm.

Specifically, the bonding layer 13 may be solid and flexible in a first temperature range and/or a first pressure range, and may have certain fluidity in a second temperature range and/or a second pressure range. Specifically, the bonding layer 13 is solid and flexible at normal temperature and pressure, or near normal temperature and pressure. The bonding layer 13 has a certain fluidity when heated to a certain temperature and/or a certain pressure is applied. Specifically, the bonding layer 13 may be a thermosetting material or a thermoplastic material.

The bonding layer 13 of different materials may be applied according to the actual use environment of the optical fiber circuit board. Specifically, when the optical fiber circuit board is required to adapt to a high-temperature environment, as described above, the optical fiber 121 may be a high-temperature optical fiber, and the bonding layer 13 may be made of at least one of an epoxy resin system, an acrylic system, and a silica gel system. The substrate 11 of the high temperature resistant material may be applied to adapt the optical fiber circuit board to a harsh high temperature environment, such that the optical fiber circuit board may be applied to special fields such as aerospace, military, etc. When the optical fiber circuit board is only required to operate in a normal temperature environment, as described above, the optical fiber 121 may be a common optical fiber, and the bonding layer 13 may be made of at least one of an acrylic system and a silica gel system. The substrate 11 may also be made of a common material.

With the bonding layer 13 of the above material, when the optical fiber circuit board is heated and/or pressurized, the bonding layer 13 may flow and cover the periphery of the optical fiber, and fill the space between the adjacent substrates 11 except the optical fiber 121. In this way, the optical fiber 121 may be fixedly secured, such that a looseness and displacement of the optical fiber 121 due to weak fixation during prolonged use may not occur, improving a reliability of the optical fiber circuit board.

In some embodiments, as shown in FIG. 1, the number of the substrates 11 is two. The two substrates 11 are stacked and spaced apart. The number of the optical fiber assembly 12 is one. The optical fiber assembly 12 is fixed between the two substrates 11 via the bonding layer 13.

In other embodiments, as shown in FIG. 2, a first substrate 11a, a second substrate 11b, and a third substrate 11c are stacked and spaced apart. A first optical fiber assembly 12a is disposed between the first substrate 11a and the second substrate 11b. A first bonding layer 13a is filled in a remaining space between the first substrate 11a and the second substrate 11b except the first optical fiber assembly 12a. The first optical fiber assembly 12a is fixed between the first substrate 11a and the second substrate. A second optical fiber assembly 12b is disposed between the second substrate 11b and the third substrate 11c. A second bonding layer 13b is filled in a remaining space between the second substrate 11b and the third substrate 11c except the second optical fiber assembly 12b. The second optical fiber assembly 12b is fixed between the second substrate 11a and the third substrate 11c.

As shown in FIG. 3, in some embodiments, the substrate 11 includes a substrate body 111 and a fiber exit opening 112. The fiber exit opening 112 is disposed at an end of the substrate body 111 along an extending direction of the optical fiber 121. It should be noted that the fiber exit opening 112 may be disposed at one end, two ends, three ends or four ends of the substrate body 111, which is not specifically limited herein.

The optical fiber 121 may be extended from the fiber exit opening 112. That is, in the extending direction of the optical fiber 121, the length of the optical fiber 121 is larger than the length of the substrate 11, such that the optical fiber 121 extending through is further connected to an optical connector. Specifically, the optical fiber 121 may include a main body portion 121a and an extending portion 121b which are connected to each other. The main body portion 121a is disposed in a region covered by two adjacent substrates 11. The extending portion 121b is disposed outside the region covered by two adjacent substrates 11.

Moreover, the optical fiber circuit board may further include a protective layer 121c wrapped around the periphery of the extending portion 121b. Specifically, the protective layer 121c may be disposed on the periphery of the extending portion 121b of each of the optical fibers 121. Or, the protective layer 121c may be disposed on the periphery of the extending portion 121b of a group of the optical fibers 121, which is not limited herein.

Specifically, the protective layer 121c may be a glue coated on the periphery of the extending portion 121b of the optical fiber 121, such as an acrylic, a resin, a polyurethane, a silicone type glue, or the like. Or, the protective layer 121c may be a protective sleeve sleeved around the periphery of the optical fiber 121, such as a heat shrinkable tube, a silicone sheath, a spiral wound tube, or the like.

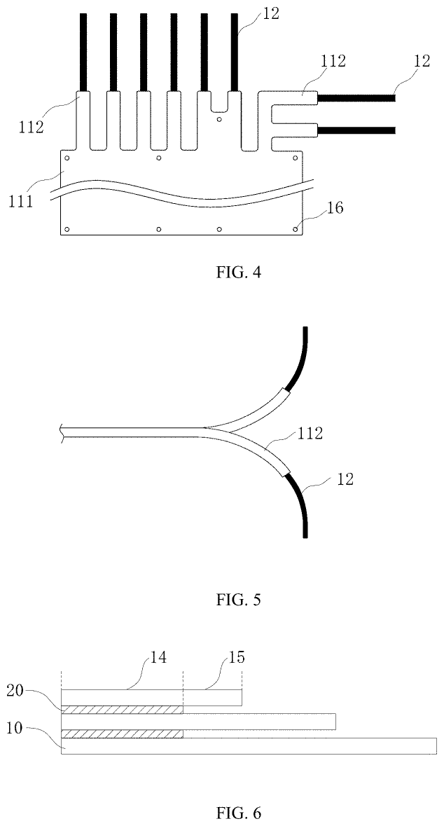

Further, as shown in FIG. 4, the number of the fiber exit openings 112 may be more than one. The plurality of fiber exit openings 112 are formed by the substrate body 111 protruding toward the periphery and extending along the extending direction of the optical fiber 121, and are spaced apart from each other. An outer edge of each fiber exit opening 112 may be flush. Each fiber exit opening 112 may correspond to a group of optical fibers 121 or a plurality of groups of optical fibers 121 spaced apart from each other.

It should be noted that, since each of the fiber exit openings 112 is spaced apart. A facing direction of each of the fiber exit openings 112 may be set according to actual needs. As shown in FIG. 4, the facing direction of the rightmost two fiber exit openings 112 is not the same as that of the left two fiber exit openings 112. Moreover, the facing direction of each of the fiber exit openings 112 may be the same. The fiber exit openings 112 may be bent, twisted, etc. according to actual needs, such that corresponding optical fibers 121 may be extended in different directions, as shown in FIG. 5.

Further, lengths of the plurality of fiber exit openings 112 in the extending direction of the optical fibers 121 may be the same or different. For example, when the direction to be set is consistent with the extending direction of the optical fibers 121 at the fiber exit openings 112, a shorter fiber exit opening 112 may be arranged. When the direction to be set has a certain angle relative to the extending direction of the optical fibers 121 at the fiber exit openings 112, even when the two directions are opposite, since a certain bending is required, a long fiber exit opening 112 may be arranged.

In the above manner, the plurality of fiber exit openings 112 are spaced apart from each other, such that each of the fiber exit openings 112 may distribute a stress generated when the optical fiber circuit board is deformed, thereby effectively reducing a risk of breakage of the optical fiber 121 at a connection between the main body portion 121a and the extending portion 121b. The plurality of fiber exit openings 112 may be arranged with various facing directions according to use needs, or the fiber exit opening 112 may be bent to achieve a large-angle deformation, thereby facilitating processing, installation and utilization.

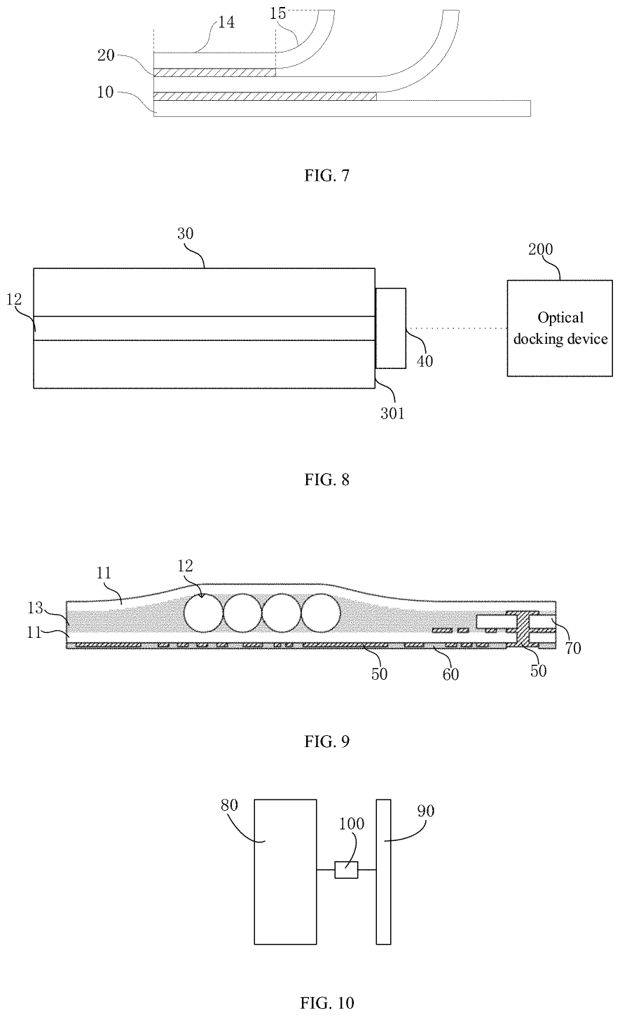

As shown in FIG. 6 and FIG. 7. FIG. 6 is a structural schematic view of a multilayer optical fiber circuit board according to an embodiment of the present disclosure. FIG. 7 is a structural schematic view of another multilayer optical fiber circuit board according to an embodiment of the present disclosure. The multilayer optical fiber circuit board may include a plurality of optical fiber circuit boards 10 and a connecting member 20 disposed between two adjacent optical fiber circuit boards 10. The plurality of optical fiber circuit boards 10 may be stacked and connected via the connecting member 20. Specifically, the number of the optical fiber circuit boards 10 may be two, three or more, which is not limited herein.

The optical fiber circuit board 10 may be the same as that according to embodiments of the present disclosure, which is not further described herein again.

Further, at least two adjacent optical fiber circuit boards 10 include a connecting region 14 and a peeling region 15. The connecting region 14 is configured for connection with other optical fiber boards 10. The peeling region 15 is not connected to other optical circuit boards 10. The peeling region 15 may be bent according to actual needs to be located at the required position. The required position may depend on the thickness of the substrate 11 and the bonding layer 13. Specifically, a positional relationship between the connecting region 14 and the peeling region 15 on the optical fiber circuit board 10 may be set according to actual needs. For example, the connecting region 14 is arranged on an end of the optical fiber circuit board 10, and the peeling region 15 is arranged on the other end. Or, the connecting region 14 is arranged on the middle of the optical fiber circuit board 10, and the peeling region 15 is arranged on both ends, which is not limited herein. It should be noted that, in the multilayer optical fiber circuit board, not necessarily each of the optical fiber circuit boards 10 includes the peeling region 15. Some of the optical fiber circuit boards 10 may not include the peeling region 15, and are integrally configured for connection with adjacent optical circuit boards 10, which is not limited herein.

Further, the connecting member 20 may be sandwiched between the two connecting regions 14 of the two adjacent optical fiber boards 10. In this way, the two connecting regions 14 of the two adjacent optical fiber boards may be connected, such that the two adjacent optical fiber boards 10 are connected. Specifically, the connecting regions 14 of the two adjacent optical fiber boards 10 are connected via the connecting member 20, such that each of the peeling regions 15 may be bent with respect to an adjacent peeling region 15.

In some embodiments, the connecting member 20 may be an adhesive layer, and the connecting regions 14 of the two adjacent optical fiber boards 10 are connected via the adhesive layer. Specifically, the adhesive layer may be acrylic, epoxy resin, polyurethane, silicone, nitrile adhesive, etc. The adhesive layer may be in a form of a liquid, a solid, a film (such as a tape), etc., which is not limited herein. In a normal use state of the multilayer optical fiber circuit board, the adhesive layer is usually a solid.

In some embodiments, the optical fiber circuit board 10 may define a mounting hole 16, as shown in FIG. 4. The connecting member 20 may be a screw, a rivet, a pin, etc. The connecting member 20 is inserted into the mounting hole 16, such that the two adjacent optical fiber boards 10 are fixed together. The fixing manner in the embodiments may enable the fixing between the adjacent optical fiber circuit boards 10 more secure and more convenient to disassemble.

It should be noted that, for various forms of the connecting member 20 and different optical fiber circuit boards 10, selections may be made according to specific conditions such as a shape, size, installation requirement, etc. of the substrate, which is not limited herein.

In the embodiments, one optical circuit board 10 may be divided into a plurality of stacked optical circuit boards 10 according to actual needs. Each optical circuit board 10 may be independently processed, tested, and replaced, thereby reducing cost and improving efficiency. In cases where a circuit board is damaged, the circuit board can be disassembled and replaced, thereby effectively reducing a risk of scrapping the entire circuit board. Further, the connecting regions 14 of the adjacent optical fiber boards 10 are connected, such that the two adjacent optical fiber boards 10 are partially connected and partially stripped to facilitate further arranging the position of the peeling region 15 according to actual needs, providing technical support and convenience for a three-dimensional installation of the multilayer fiber optic circuit boards.

As shown in FIG. 8, FIG. 8 is a structural schematic view of an optical transmission device according to an embodiment of the present disclosure. The optical transmission device includes an optical fiber circuit board and/or a multilayer optical fiber circuit board (collectively indicated as a circuit board 30) and an optical port 40 disposed on an end portion 301 of the circuit board 30. The optical port 40 is configured to receive the optical fiber 12 in the circuit board 30 and is further connected to an optical docking device 200 for optical signal transmission. The optical docking device 200 may be a light energy converter or a light transmitting medium. The light energy converter may be a photoelectric converter. The optical transmission medium may be an optical fiber, an organic waveguide, an inorganic waveguide, or the like. The circuit board 30 may be that described in the foregoing embodiments, which is not described herein again.

As shown in FIG. 9, FIG. 9 is a structural schematic view of a photo-electric hybrid circuit board according to an embodiment of the present disclosure. The photo-electric hybrid circuit board includes an optical fiber circuit board and/or a multilayer optical fiber circuit board (the optical fiber circuit board 10 is taken as an example in FIG. 9) and a circuit conductor 50 disposed on the optical fiber circuit board and/or the multilayer optical fiber circuit board. The optical fiber circuit board and the multilayer optical fiber circuit board may be those described in the foregoing embodiments, which is not described herein again. In the photo-electric hybrid circuit board, the optical fiber is configured to transmit a large number of high-speed signals, and the circuit wire is configured to transmit low-frequency signals and control signals.

The circuit wire 50 may be a metal wire. Specifically, the metal wire may be a copper wire. The circuit wire 50 may be disposed on any one or more of the substrates 11 of the optical circuit board 10.

The substrate 11 arranged with the circuit wire 50 may be coated with a protective layer 60 for covering the circuit wire 50 to protect the same. Specifically, the protective layer 60 may be a liquid photo solder resist.

It should be noted that the protective layer 60 is generally disposed on an outer surface of the substrate 11 away from the optical fiber 121, and is not disposed on an inner surface of the substrate 11 near the optical fiber 121. Specifically, the protective layer 60 is disposed on the outer surface of the top substrate 11 of the photo-electric hybrid circuit board and the outer surface of the bottom substrate 11.

The circuit wire 50 may also be disposed between adjacent substrates 11. Specifically, the circuit wire 50 may be disposed in a space between adjacent two substrates 11 corresponding to a region other than the fiber assembly 12. The circuit wire 50 disposed between the adjacent two substrates 11 may be a single layer or two or more layers, which may be specifically arranged according to actual needs. A medium layer 70 may be disposed between the circuit wires 50 of adjacent layers. The medium layer 70 may be configured to at least partially separate the circuit wires 50 of different layers, maintaining an insulation. Of course, the circuit wires 50 of different layers may be further connected by punching.

As shown in FIG. 10, FIG. 10 is a structural schematic view of a signal transmission device according to an embodiment of the present disclosure. In the embodiments, the signal transmission device may include at least one of a optical fiber circuit board, a multilayer optical fiber circuit board, and an photo-electric hybrid circuit board (indicated by a circuit board 80), a signal transmission mechanism 90, a fixing member 100, and the like. The fixing member 100 is configured to fix the circuit board 80 to the signal transmission mechanism 90.

The signal transmission device in the present embodiments may be configured to transmit an optical signal, an photo-electric hybrid signal, or a mixed signal of an optical signal and other signals. The signal transmission mechanism 90 may specifically be a circuit board, a cabinet, a distribution frame, or the like.

It should be noted that the optical fiber circuit board may be the same as that according to embodiments of the present disclosure, the multilayer optical fiber circuit board may be the same as that according to embodiments of the present disclosure, and the photo-electric hybrid circuit board may be the same as that according to embodiments of the present disclosure, which is not further described herein again.

In addition, similar to the connecting member 20 in foregoing embodiments, the fixing component 100 in the embodiments may be an adhesive layer, and specifically may be acrylic, epoxy resin, polyurethane, silicone, nitrile adhesive, etc. The adhesive layer may be in a form of a liquid, a solid, a film (such as a tape), etc. Or, a mounting hole may be defined on the circuit board 80. The fixing member 100 may be may be a screw, a rivet, a pin, etc. The fixing member 100 is inserted into the mounting hole, such that the fiber board 80 and the signal transmission mechanism 90 are fixed together. The fixing manner in the embodiments may enable the fixing between the fiber board 80 and the signal transmission mechanism 90 more secure and more convenient to disassemble.

It should be noted that, in addition to the above manner, the circuit board 80 and the signal transmission mechanism 90 may be connected and fixed by pressing.

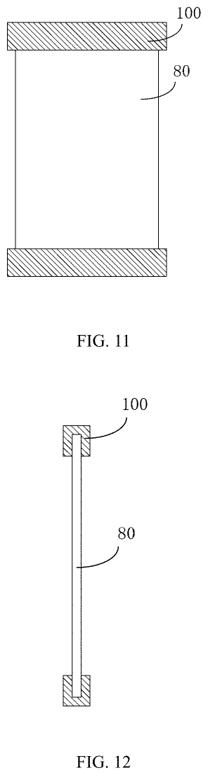

In some embodiments, as shown in FIG. 11 and FIG. 12, the fixing member 100 may be a buckle. The buckle is disposed at an outer edge of the circuit board 80. The circuit board 80 may be fixed to positions of a gap, a card slot, etc., of the signal transmission mechanism by the buckle, such that the circuit board 80 may be pressed and fixed.

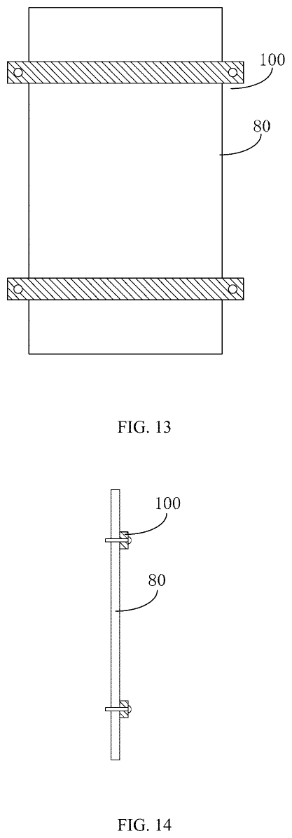

In other embodiments, as shown in FIG. 13 and FIG. 14, the fixing member 100 may include a pressing block and a screw. Specifically, the circuit board 80 may be pressed against the signal transmission mechanism by the pressing block. Further, the pressing block is fixed to the signal transmission mechanism on both sides of the circuit board 80 by the screw. In this way, the circuit board 80 is clamped between the pressing block and the signal transmission mechanism. The screw may also be replaced by other components, such as a rivet, a pin, etc., which is not limited herein.

According to the pressing method described above, a mounting hole is not required to be defined to occupy an intra-board wire space of the circuit board 80, and an installation is easier, compared to the method of defining mounting holes on the circuit board 80.

It should be noted that the various forms of the above-mentioned fixing members may be selected according to the shape, size, and installation requirements of the substrate in the circuit board 80, which is not limited herein.

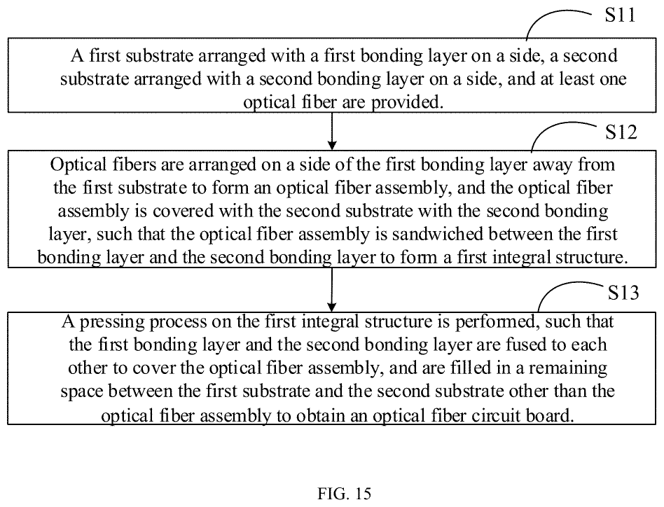

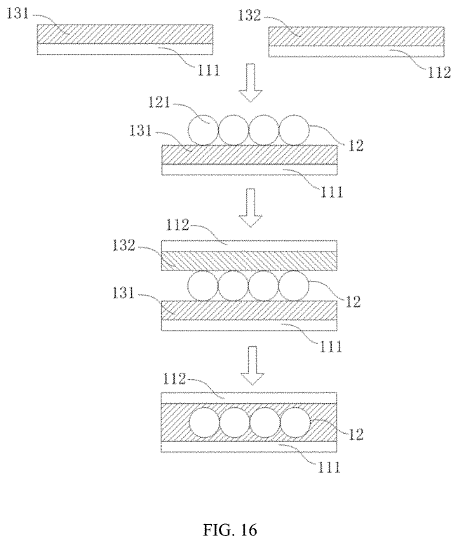

As shown in 15 and FIG. 16, FIG. 15 is a flow chart of a method for manufacturing an optical fiber circuit board according to an embodiment of the present disclosure, and FIG. 16 is a schematic view of related structures in FIG. 15. The method may be performed for manufacturing the optical fiber circuit board including only two layers of substrates. Specifically, the method includes operations at blocks illustrated in FIG. 15.

At block S11: A first substrate 111 arranged with a first bonding layer 131 on a side, a second substrate 112 arranged with a second bonding layer 132 on a side, and at least one optical fiber 121 are provided.

Specifically, the first substrate 111 and the second substrate 112 are each arranged with a bonding layer on a side and no bonding layer on the other side.

The first substrate 111 on which the first bonding layer 131 is disposed on a side may be obtained by disposing the first bonding layer 131 on a side of the first substrate 111. Or, the first substrate 111 arranged with the first bonding layer 131 may be directly acquired, which is not limited herein. Similarly, the second substrate 112 arranged with the second bonding layer 132 on a side may also be obtained in the above manner.

At block S12: Optical fibers 121 are arranged on a side of the first bonding layer 131 away from the first substrate 111 to form an optical fiber assembly 12, and the optical fiber assembly 12 is covered with the second substrate 112 with the second bonding layer 132, such that the optical fiber assembly 12 is sandwiched between the first bonding layer 131 and the second bonding layer 132 to form a first integral structure.

At block S13: A pressing process on the first integral structure is performed, such that the first bonding layer 131 and the second bonding layer 132 are fused to each other to cover the optical fiber assembly 12, and are filled in a remaining space between the first substrate 111 and the second substrate 112 other than the optical fiber assembly 12 to obtain an optical fiber circuit board.

It should be noted that since the first bonding layer 131 and the second bonding layer 132 have a certain fluidity under heating and/or pressure conditions, the pressing process enables the first bonding layer 131 and the second bonding layer 132 to be fused together and filled into the space between the first substrate 111 and the second substrate 112 other than the optical fiber assembly 12, thereby fixing the optical fiber 121 more firmly to reduce a looseness and displacement of the optical fiber 121 due to weak fixation during prolonged use. When the pressing process is performed, air bubbles inside the bonding layer, those between the bonding layer and the optical fiber, and those between the bonding layer and the substrate are discharged, thereby improving the reliability of the optical circuit board. Moreover, the optical fiber circuit board prepared by the above method is difficult to stratify and foam under repeated bending and thermal shock, and thus has a good stability.

After the first integral structure is pressed, the first integral structure may be further baked, such that the substrates and the optical fibers 121 may be firmly integral.

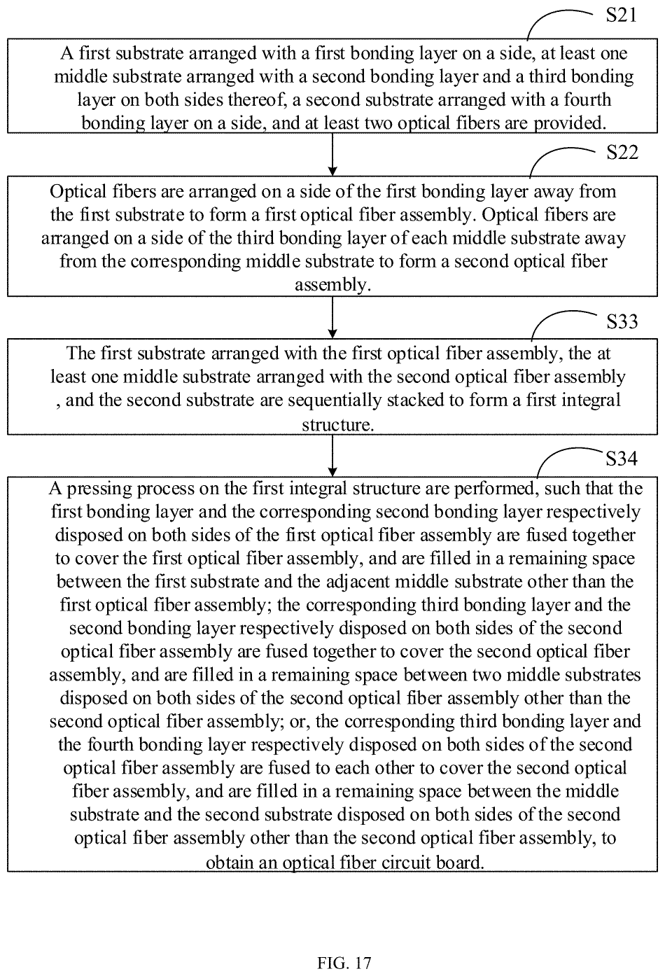

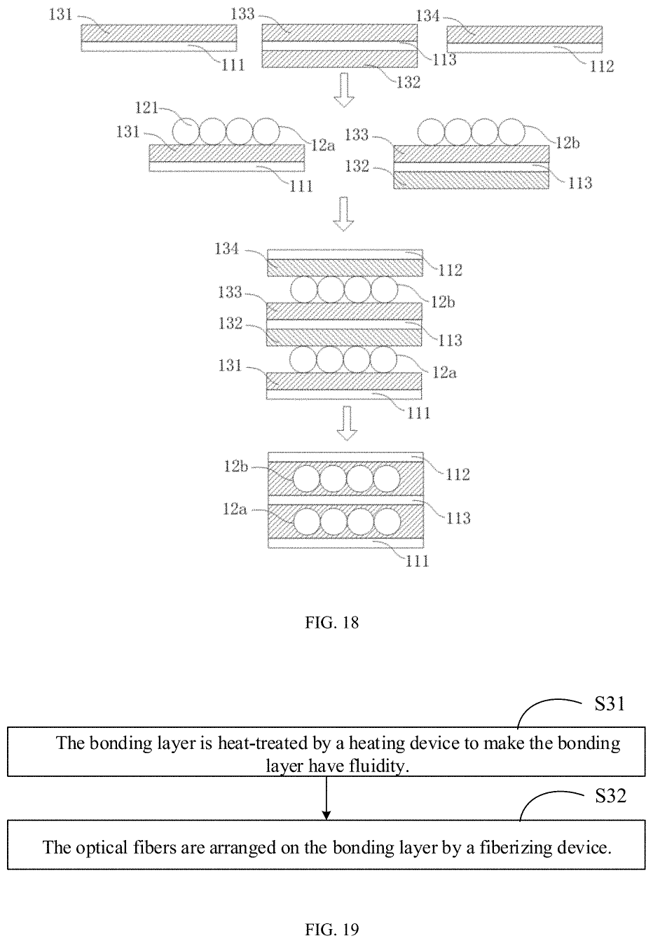

As shown in 17 and FIG. 18, FIG. 17 is a flow chart of a method for manufacturing an optical fiber circuit board according to another embodiment of the present disclosure. FIG. 18 is a schematic view of related structures in FIG. 17. The method of the embodiments may be performed to prepare the optical fiber circuit board including three or more substrates. Specifically, the method includes operations at blocks illustrated in FIG. 17.

At block S21: A first substrate 111 arranged with a first bonding layer 131 on a side, at least one middle substrate 113 arranged with a second bonding layer 132 and a third bonding layer 133 on both sides thereof, a second substrate 112 arranged with a fourth bonding layer 134 on a side, and at least two optical fibers are provided.

The first substrate 111 on which the first bonding layer 131 is disposed on a side may be obtained by disposing the first bonding layer 131 on a side of the first substrate 111. Or, the first substrate 111 arranged with the first bonding layer 131 may be directly acquired, which is not limited herein. Similarly, the at least one middle substrate 113 arranged with the second bonding layer 132 and the third bonding layer 133 disposed on both sides thereof, and the second substrate 112 arranged with the fourth bonding layer 134 on a side may also be obtained in the above manner.

At block S22: Optical fibers 121 are arranged on a side of the first bonding layer 131 away from the first substrate 111 to form a first optical fiber assembly 12a. Optical fibers 121 are arranged on a side of the third bonding layer 133 of each middle substrate 113 away from the corresponding middle substrate 113 to form a second optical fiber assembly 12b.

At block S23: The first substrate 111 arranged with the first optical fiber assembly 12a, the at least one middle substrate 113 arranged with the second optical fiber assembly 12b, and the second substrate 112 are sequentially stacked to form a first integral structure.

In the first integral structure, the first optical fiber assembly 12a is sandwiched between the first bonding layer 131 and the corresponding second bonding layer 132. The second optical fiber assembly 12b is sandwiched between the corresponding third bonding layer 133 and the second bonding layer 132, or between the corresponding third bonding layer 133 and the fourth bonding layer 134.

Arrangements of the first fiber assembly 12a and the second fiber assembly 12b may be the same or different. When the number of the middle substrates 113 is two or more, arrangements of the optical fiber assemblies 12 corresponding to different middle substrates 113 may also be the same or different, and can be arranged according to actual needs.

At block S24: A pressing process on the first integral structure are performed, such that the first bonding layer 131 and the corresponding second bonding layer 132 respectively disposed on both sides of the first optical fiber assembly 12a are fused together to cover the first optical fiber assembly 12a, and are filled in a remaining space between the first substrate 111 and the adjacent middle substrate 113 other than the first optical fiber assembly 12a; the corresponding third bonding layer 133 and the second bonding layer 132 respectively disposed on both sides of the second optical fiber assembly 12b are fused together to cover the second optical fiber assembly 12b, and are filled in a remaining space between two middle substrates 113 disposed on both sides of the second optical fiber assembly 12b other than the second optical fiber assembly 12b; or, the corresponding third bonding layer 133 and the fourth bonding layer 134 respectively disposed on both sides of the second optical fiber assembly 12b are fused to each other to cover the second optical fiber assembly 12b, and are filled in a remaining space between the middle substrate 113 and the second substrate 112 disposed on both sides of the second optical fiber assembly 12b other than the second optical fiber assembly 12b, to obtain an optical fiber circuit board.

It is to be noted that the number of the middle substrates 113 in the present embodiments may be one or more than one. When the number of the middle substrates 113 is one, the middle substrate 113 is disposed between the first substrate 111 and the second substrate 112. The first optical fiber assembly 12a and a corresponding bonding layer are disposed between the first substrate 111 and the middle substrate 112. The second optical fiber assembly 12b and a corresponding bonding layer are disposed between the second substrate 112 and the middle substrate 113. When the number of the middle substrates 113 is two, the two middle substrates 113 are stacked and disposed between the first substrate 111 and the second substrate 112. On two sides of a first one of the two middle substrates 113, the first substrate 111 and a second middle substrate 113 are arranged. On two sides of the second one of the two middle substrates 113, the second substrate 112 and the first one middle substrate 113 are arranged. The first optical fiber assembly 12a and the corresponding bonding layer are disposed in the same manner as described above. Specifically, one of the second optical fiber assemblies 12b and its corresponding bonding layer are disposed between the two middle substrates 113, and another second optical fiber assembly 12b and its corresponding bonding layer are disposed between the middle substrate 113 and the second substrate 112.

Other related technical solutions are the same as foregoing embodiments of the present disclosure, and details are not described herein again.

Further, as shown in FIG. 19, in some embodiments, operations of the disposing optical fibers on the bonding layer of each of the substrates includes operations at blocks illustrated in FIG. 19.

At block S31: The bonding layer 13 is heat-treated by a heating device to make the bonding layer 13 have fluidity.

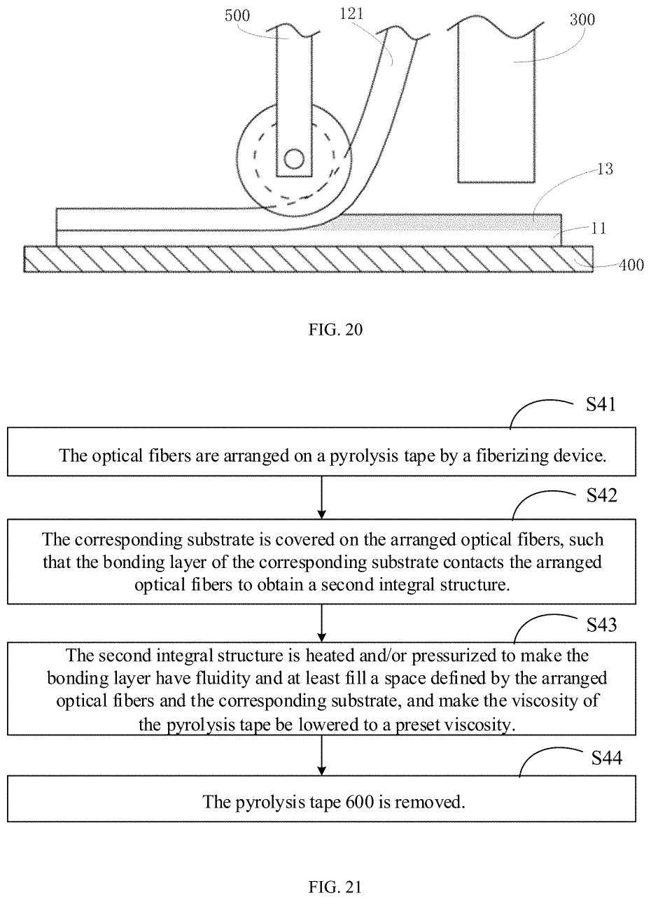

Specifically, as shown in FIG. 20, the bonding layer 13 may be directly subjected to heat treatment by the heating device, or the substrate 11 may be subjected to heat treatment by the heating device to realize the heat treatment of the bonding layer 13. The heating device may be a local heating device 300 or a full heating device 400 such as a heating base, or a combination of the two. Moreover, the heat treatment of the bonding layer 13 may be one of heat gun heating, hot conductor contact heating, infrared radiation heating, ultrasonic vibration heating, or the like, or may be a combination of the above. For example, the entire substrate 11 may be heat-treated, and then an area in which the optical fibers 121 are required to be arranged is concentrated heat-treated, thereby improving heating and fabricating efficiency.

At block S32: The optical fibers 121 are arranged on the bonding layer by a fiberizing device 500.

The bonding layer 13 includes the first bonding layer 131 disposed on the first substrate 111 and the third bonding layer 133 disposed on the middle substrate 113 as described above.

In addition, other related detailed description of the optical fiber circuit board are described in the foregoing embodiments of optical fiber circuit board, and details are not described herein again.

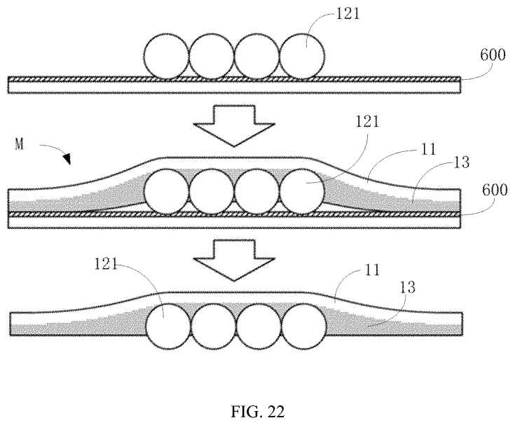

Further, as shown in FIG. 21 and FIG. 22, in other embodiments, operations of the disposing optical fibers on the bonding layer of each of the substrates includes operations at blocks illustrated in FIG. 21.

At block S41: The optical fibers 121 are arranged on a pyrolysis tape 600 by a fiberizing device.

The pyrolysis tape 600 has viscosity at normal temperature, and can be heated to a very low viscosity state by heating at a certain temperature. In this way, the pyrolysis tape 600 can be easily separated from the surface to which it is attached.

At block S42: The corresponding substrate 11 is covered on the arranged optical fibers, such that the bonding layer of the corresponding substrate contacts the arranged optical fibers to obtain a second integral structure.

At block S43: The second integral structure is heated and/or pressurized to make the bonding layer 13 have fluidity and at least fill a space defined by the arranged optical fibers and the corresponding substrate, and make the viscosity of the pyrolysis tape 600 be lowered to a preset viscosity.

The heating and/or pressurizing here is the same as that in the above embodiments, and are not described herein again.

The preset viscosity of the pyrolysis tape 600 may refer to a viscosity at which the pyrolysis tape 600 can be easily removed from the optical fiber 121.

At block S44: The pyrolysis tape 600 is removed.

The bonding layer 13 includes the first bonding layer 131 disposed on the first substrate 111 and the third bonding layer 133 disposed on the middle substrate 113 as described above.

In addition, other related detailed description of the optical fiber circuit board are described in the foregoing embodiments of optical fiber circuit board, and details are not described herein again.

The above description is for the purpose of illustrating implementations of the present disclosure, but not to limit the scope of the present disclosure. Any equivalent structural or process transformation performed based on the drawings and the specification of the present disclosure, applied directly and indirectly in other related art, should be within the scope of the present disclosure.

What is claimed is:

1. An optical fiber circuit board, comprising:
at least two substrates stacked and spaced apart;
at least one optical fiber assembly, wherein each of the at least one optical fiber assembly is disposed between each adjacent two of the at least two substrates; each of the at least one optical fiber assembly comprises at least one optical fiber; and
a bonding layer, filled in a remaining space between adjacent two of the at least two substrates apart from a corresponding optical fiber assembly of the at least one optical fiber assembly to fix each of the at least one optical fiber relative to the adjacent two substrates.

2. The optical fiber circuit board according to claim 1, wherein the bonding layer is in a solid state under at least one condition of being in a first temperature range and a first pressure range, and has a fluidity under at least one condition of being in a second temperature range and a second pressure range; wherein any temperature value in the first temperature range is equal to or less than any temperature value in the second temperature range.

3. The optical fiber circuit board according to claim 2, wherein the bonding layer is made of a thermosetting material or a thermoplastic material.

4. The optical fiber circuit board according to claim 1, wherein the substrate is made of a flexible material.

5. The optical fiber circuit board according to claim 1, wherein the at least one optical fiber is a common optical fiber, and the bonding layer is made of at least one of an acrylic system and a silica gel system.

6. The optical fiber circuit board according to claim 1, wherein the at least one optical fiber is a high temperature optical fiber, and the bonding layer is made of at least one of an epoxy resin system, an acrylic system, and a silica gel system.

7. The optical fiber circuit board according to claim 1, wherein a thickness of a thinnest region of the bonding layer between the adjacent two substrates is larger than a tenth of a diameter of the at least one optical fiber and smaller than 10 times of the diameter of the at least one optical fiber.

8. The optical fiber circuit board according to claim 7, wherein a thickness of a thinnest region of the bonding layer between the adjacent two substrates is larger than a half of a diameter of the at least one optical fiber and smaller than 2 times of the diameter of the at least one optical fiber.

9. The optical fiber circuit board according to claim 1, wherein the at least one optical fiber assembly comprises at least one optical fiber arranged in a single layer.

10. The optical fiber circuit board according to claim 1, wherein the at least one optical fiber assembly comprises a plurality of optical fibers stacked and staggered, or stacked and cross-arranged.

11. The optical fiber circuit board according to claim 1, wherein each of the at least two substrates comprises a substrate body portion and at least one fiber exit opening, each of the at least one fiber exit opening is disposed at an end of the substrate body portion along an extending direction of at least one corresponding optical fiber of the at least one optical fiber; wherein the at least one corresponding optical fiber extends from the fiber exit opening.

12. The optical fiber circuit board according to claim 11, wherein the number of the at least one fiber exit opening is more than one; the more than one fiber exit openings are formed by the substrate body portion protruding toward a periphery and extending, and are spaced apart from each other.

13. The optical fiber circuit board according to claim 1, wherein the each of the at least one optical fiber comprises:
a main body portion, disposed in a region covered by corresponding adjacent two substrates of the at least two substrates; and
an extending portion, connected to the main body portion and disposed outside the region covered by corresponding adjacent two substrates of the at least two substrates;
wherein the optical fiber circuit board further comprises a protective layer wrapped around a periphery of the extending portion.

14. A multilayer optical fiber circuit board, comprising: a plurality of optical fiber circuit boards, comprising:
at least two substrates stacked and spaced apart;
at least one optical fiber assembly, wherein each of the at least one optical fiber assembly is disposed between each adjacent two of the at least two substrates; each of the at least one optical fiber assembly comprises at least one optical fiber; and
a bonding layer, filled in a remaining space between adjacent two of the at least two substrates apart from a corresponding optical fiber assembly of the at least one optical fiber assembly to fix each of the at least one optical fiber relative to the substrate;
and at least one connecting member disposed between two adjacent optical fiber circuit boards of the plurality of optical fiber circuit boards, wherein the plurality of optical fiber circuit boards are stacked and connected via the at least one connecting member.

15. The multilayer optical fiber circuit board according to claim 14, wherein the at least one connecting member is an adhesive layer, and each of at least two adjacent optical fiber circuit boards of the plurality of optical fiber circuit boards comprises a connecting region and a peeling region;
each of the at least one connecting member is sandwiched between two connecting regions of two adjacent optical fiber circuit boards of the plurality of optical fiber circuit boards, and is configured to connect the two connecting regions, such that the two adjacent optical fiber circuit boards of the plurality of optical fiber circuit boards are connected.

16. The multilayer optical fiber circuit board according to claim 15, wherein the two connecting regions of the two adjacent optical fiber circuit boards are connected via the connecting member such that the peeling region is bent relative to an adjacent peeling region.

17. A photo-electric hybrid circuit board comprising at least one circuit board of an optical fiber circuit board and an multilayer optical fiber circuit board, and a circuit wire disposed on the at least one circuit board;
wherein the optical fiber circuit board comprises:
at least two substrates stacked and spaced apart;
at least one optical fiber assembly, wherein each of the at least one optical fiber assembly is disposed between each adjacent two of the at least two substrates; each of the at least one optical fiber assembly comprises at least one optical fiber; and
a bonding layer, filled in a remaining space between adjacent two of the at least two substrates apart from a corresponding optical fiber assembly of the at least one optical fiber assembly to fix each of the at least one optical fiber relative to the substrate;
the multilayer optical fiber circuit board comprises:
a plurality of the optical fiber circuit boards;
and at least one connecting member disposed between two adjacent optical fiber circuit boards of the plurality of optical fiber circuit boards, wherein the plurality of optical fiber circuit boards are stacked and connected via the at least one connecting member.

18. The photo-electric hybrid circuit board according to claim 17, wherein the circuit wire is disposed on the at least one substrate.

19. The photo-electric hybrid circuit board according to claim 18, wherein the at least one substrate is coated with a protective layer for covering the circuit wire; the protective layer is a liquid photo solder resist.

20. The photo-electric hybrid circuit board according to claim 17, wherein the circuit wire is disposed in a region between adjacent two substrates of the at least one substrate corresponding to the at least one optical fiber assembly.
